(19) United States
(12) Patent Application Publication
(10) Pub. No.: US 2011/0193223 A1
(43) Pub. Date: Aug. 11, 2011

(54) SEMICONDUCTOR DEVICE, CHIP-ON-CHIP MOUNTING STRUCTURE, METHOD OF MANUFACTURING THE SEMICONDUCTOR DEVICE, AND METHOD OF FORMING THE CHIP-ON-CHIP MOUNTING STRUCTURE

(75) Inventors: Hiroshi Ozaki, Kanagawa (JP); Hiroshi Asami, Shizuoka (JP)

(73) Assignee: SONY CORPORATION, Tokyo (JP)

(21) Appl. No.: 13/018,723

(22) Filed: Feb. 1, 2011

(30) Foreign Application Priority Data
Feb. 9, 2010 (JP) 2010-026484

(51) Int. Cl. H01L 23/498; H01L 21/60

(52) U.S. Cl. 257/737; 438/614; 438/107; 257/E23.068; 257/E21.506

(57) ABSTRACT

A semiconductor device includes: a semiconductor chip having a semiconductor substrate; a pad electrode formed on the semiconductor substrate; a base metal layer formed on said pad electrode; and a bump electrode formed on the base metal layer, in which an exposed surface including a side surface of the base metal layer is covered with the solder bump electrode.

### BACKGROUND OF THE INVENTION

1. Field of the Invention

The present invention relates to a semiconductor device suitable for manufacturing an electronic apparatus, a Chip-on-Chip mounting structure using the semiconductor device, a method of manufacturing the semiconductor device, and a method of forming the Chip-on-Chip mounting structure using the semiconductor device.

2. Description of the Related Art

Heretofore, a semiconductor device having solder bump electrodes has been used as a key part of electronic apparatuses such as video equipment such as a television receiver, audio equipment, a mobile phone, and a personal computer.

FIGS. 4A to 4O show processes for manufacturing a semiconductor chip as a semiconductor device 65, respectively. These manufacturing processes, for example, are disclosed in “Introduction of CASIO solder BUMP technology (Smart & Fine Technologies)” which will be described later.

Firstly, as shown in FIG. 4A, an insulating film 64 for guiding a wiring (not shown) from an internal circuit to an external terminal is formed on a semiconductor substrate 51 made of Si or the like. Also, a pad electrode 52 made of aluminum is formed in a predetermined position on the insulating film 64. In this case, although the wiring connected to the semiconductor substrate 51 is derived to the pad electrode 52 through the insulating film 64, an illustration of this deriving structure is omitted here (and so forth on).

Next, as shown in FIG. 4B, a surface protective film 53 is formed on the insulating film 64 so as to partially cover the pad electrode 52 by Ar plasma etching.

Next, as shown in FIG. 4C, a Ti layer 54 for enhancing a coating property of an upper layer is formed on the entire surface of the protective film 53 by sputtering.

Next, as shown in FIG. 4D, a Cu layer 55 which becomes an electrode in a phase of electrolytic plating is formed on the entire surface of the Ti layer 54 by sputtering.

Next, as shown in FIG. 4E, a photo resist 56 which, for example, is a positive type is formed on the Cu layer 55 by application.

Next, as shown in FIG. 4F, a predetermined position (that is, on the pad electrode 52) of the positive photo resist 56 is exposed by using a mask 63 for exposure. Also, as shown in FIG. 4G, the exposed portion of the positive photo resist 56 is dissolved and removed away to form an opening portion in the positive photo resist 56, and residues are then removed away.

Next, as shown in FIG. 4H, the electrolytic plating for a Ni layer 57 is carried out for the opening portion with the Cu layer 55 and the positive photo resist 56 as an electrode and a mask, respectively. As a result, a Ni electrolytic plating layer 57 composing an Under Bump Metal (UBM) is selectively formed only on the pad electrode 52. The Ni electrolytic plating layer 57 has a barrier operation as a base of a solder bump electrode which will be described later. That is to say, when the solder bump electrode is directly formed on the Cu layer 55, the Cu layer 55 is corroded, and thus the electrode characteristics in a phase of the electrolytic plating for the solder bump electrode become deteriorated. However, in order to prevent this situation, the Ni electrolytic plating layer 57 acts as a barrier layer, thereby making it possible to protect the Cu layer 55 from being corroded.

Next, as shown in FIG. 4I, a Sn—Ag alloy layer 58a (a ratio of Sn to Ag is 97:3) is electrolytically plated on the Ni electrolytic plating layer 57 with the Cu layer 55 as the electrode.

Next, as shown in FIG. 4J, the photo resist 56 is entirely removed away.

Next, as shown in FIG. 4K, the Cu layer 55 is subjected to wet etching with the Sn—Ag alloy layer 58a as an etching mask, thereby removing away an unnecessary portion of the Cu layer 55. In this case, although the Cu layer 55 is under-etched, this state is not illustrated.

Next, as shown in FIG. 4L, subsequently, the Ti layer 54 is selectively removed away except for a portion of the Ti layer 54 underlying the Sn—Ag alloy layer 58a with the Sn—Ag alloy layer 58a as a mask by the wet etching. As a result, the Ti layer 54 (in addition, the Cu layer 55) has a pattern with which the adjacent solder bump electrodes are electrically separated from each other.

Next, as shown in FIG. 4M, a flux layer 59 is deposited so as to cover the entire surface including the Sn—Ag alloy layer 58a. The flux layer 59 acts as a reducing agent and thus dissolves and removes away a surface oxide film of the solder bump electrode material.

Next, as shown in FIG. 4N, a reflow treatment is carried out to melt the Sn—Ag alloy layer 58, thereby forming a solder bump electrode 58.

Next, as shown in FIG. 4O, the flux layer 59 is removed away and a desired semiconductor device (semiconductor chip) 65 is obtained through scribing.

The semiconductor device 65 thus obtained is mounted by using the Chip-on-Chip system in a fluxless fashion. FIGS. 5A to 5D show processes for mounting the semiconductor device 65, respectively.

Firstly, as shown in FIG. 5A, upper and lower semiconductor devices (semiconductor chips) 65A and 65B each having a pad electrode and a solder bump electrode identical in structure to those of the semiconductor device 65 described above are aligned with each other in such a way that the solder bump electrode 58 of the upper semiconductor device 65A, and the solder bump electrode 58 of the lower semiconductor device 65B face each other.

Next, as shown in FIG. 5B, the upper semiconductor device 65A is made to contact the lower semiconductor device 65B under the condition of application of heat, and application of pressure. Also, the solder bump electrode 58 of the upper semiconductor device 65A is made to contact the solder bump electrode 58 of the lower semiconductor device 65B in a heating and melting state. At this time, surface oxide films of the solder bump electrodes 58 of the upper semiconductor device 65A and the lower semiconductor device 65B are torn, thereby making it possible to reduce a contact resistance between both the solder bump electrodes 58.

Next, as shown in FIG. 5C, the upper semiconductor device 65A is further pressed against the lower semiconductor device 65B, whereby both the solder bump electrodes 58 of the upper semiconductor device 65A and the lower semiconductor device 65B run over in a transverse direction in the drawing while they are sufficiently fused.

Next, as shown in FIG. 5D, a gap defined between the upper semiconductor device 65A and the lower semiconductor device 65B is adjusted and cooling is carried out, thereby making it possible to form a thinned mounting structure 66 using a Chip-on-Chip system.

As has been described, in the case of the mounting structure 66 using the Chip-on-Chip system formed under the fluxless condition accompanied by the application of the pressure, after completion of the mounting, a difficult work for injecting a cleaning liquid necessary for cleaning and removal of the flux through a narrow space defined between both the upper and lower semiconductor devices becomes unnecessary as compared with the case where both the solder bump electrodes are fused by using the flux.

### SUMMARY OF THE INVENTION

As described above, the upper and lower semiconductor devices 65A and 65B each having the solder bump electrode 58 on the upper surface of the UBM layer 62 composed of the Ni layer 57, the Cu layer 55 and the Ti layer 54 are used when the mounting structure 66 using the Chip-on-Chip system is formed. FIG. 6A is an enlarged cross sectional view of a main portion of each of the upper and lower semiconductor devices 65A and 65B. Also, as shown in FIG. 6B, when both the upper and lower semiconductor devices 65A and 65B are bonded to each other in the fluxless fashion through the solder bump electrodes 58, the solder bump electrodes 58 are excessively crushed to become easy to run over in the transverse direction depending on the dispersions of the volume of the solder, and the bonding condition.

At this time, when the adjacent solder bump electrodes 58 are made close to each other in each of the upper and lower semiconductor devices 65A and 65B, and thus a transverse size of the mounting structure is desired to be reduced, especially, the adjacent solder bump electrodes 58 each running over in the transverse direction contact each other. As a result, since the surface oxide film in the contact surface between both the solder bump electrodes 58 is torn due to the pressure in a phase of the contact of the adjacent solder bump electrodes 58, the short-circuit is electrically caused to generate a failure.

In addition, if the short-circuit described above is not generated between the adjacent solder bump electrodes 58 in one semiconductor device as shown in FIG. 5C, when an interval between the adjacent solder bump electrodes is reduced, a transverse thickness of an underfill material (not shown) made from an epoxy resin filled in the space defined between the upper and lower semiconductor devices becomes easy to be small, including the interval, so as to correspond to the running-over amount of solder bump electrodes. As a result, electromigration is generated such that Sn atoms move between the adjacent solder bump electrodes through fine pores in the underfill material, and also causes the short-circuit.

The present invention has been made in order to solve the problems described above, and it is therefore desirable to provide a semiconductor device in which an amount of solder bump electrodes transversely running-over (protrusion amount) is reduced when semiconductor devices are mounted in accordance with a Chip-on-Chip system with adjacent solder bump electrodes being disposed close to each other in a transverse direction, thereby providing a high yield free from short-circuit, and high reliability, a Chip-on-Chip mounting structure using the semiconductor device, a method of manufacturing a semiconductor device, and a method of forming the Chip-on-Chip mounting structure.

In order to attain the desire described above, according to an embodiment of the present invention, there is provided a semiconductor device including: a semiconductor chip having a semiconductor substrate; a pad electrode formed on the semiconductor substrate; a base metal layer formed on the pad electrode; and a solder bump electrode formed on the base metal layer, in which an exposed surface including a side surface of the base metal layer is covered with the solder bump electrode.

According to another embodiment of the present invention, there is provided a Chip-on-Chip mounting structure, in which the plurality of semiconductor devices each according to the embodiment are joined to one another through the solder bump electrodes.

According to still another embodiment of the present invention, there is provided a method of manufacturing a semiconductor device including the steps of: forming a pad electrode on a semiconductor substrate; forming a base metal layer on the pad electrode; and forming a solder bump electrode on the base metal layer, an exposed surface including a side surface of the base metal layer being covered with a material composing the solder bump electrode.

According to yet another embodiment of the present invention, there is provided a method of forming a Chip-on-Chip mounting structure including the steps of: causing the plurality of semiconductor devices each obtained by the manufacturing method according to the still another embodiment to contact one another through the solder bump electrodes; melting the solder bump electrodes under a condition of application of heat, and application of pressure in this state; and solidifying the solder bump electrodes, for joining the plurality of semiconductor devices to one another.

The inventor of this application checked up about the existing solder bump structure described above. As a result, as shown in FIG. 6A, since the photo resist 56 is commonly used, and the solder bump electrode 58 is formed in the same pattern as that of the Ni layer 57 by the electrolytic plating, the solder bump electrode 58 is formed only on the upper surface of the UBM layer 62. For this reason, it was found out that as shown in FIG. 6B, the solder melted under the application of the pressure in the fluxless fashion is repelled by the Ni oxide film formed on the side surface of the UBM layer 62 to run over in the transverse direction with the melted solder not being adhered to the side surface of the UBM layer 62. That is to say, since the melted solder does not adhere to the side surface of the UBM layer 62, the amount of melted solder running over in the transverse direction increases.

However, according to the present invention, the exposed surface including the side surface of the base metal layer (corresponding to the UBM layer) is covered with the solder bump electrode described above. Thus, in particular, in the Chip-on-Chip mounting carried out in the fluxless fashion, the amount of solder running over in the transverse direction (amount of protrusion) decreases by the amount of the melted solder of the solder bump electrode adhered to the side surface of the base metal layer. Also, the solder bump electrodes disposed adjacent and close to each other in the semiconductor device are prevented from contacting each other, and thus even when the oxide film of the solder surface smashes due to the pressure in a phase of bulging caused by the application of the pressure, it is possible to prevent the short-circuit from being generated between the adjacent solder bump electrodes. As a result, even when the interval between the adjacent solder bump electrodes is reduced, the yield and reliability of the bonding are enhanced.

In addition, when the underfill material is filled in the space defined between both the semiconductor devices joined to each other, since the amount of solders each running over of the solder bump electrodes is reduced, a thickness of the underfill material between the adjacent solder bump electrodes increases accordingly. As a result, the elements (especially, Sn atoms) composing the solder become difficult to move between the adjacent solder bump electrodes through the underfill material. Thus, it is possible to prevent the electromigration from being generated, and it is also possible to increase the margin of the interval and disposition between the adjacent solder bump electrodes.

### BRIEF DESCRIPTION OF THE DRAWINGS

FIGS. 1A and 1B are a cross sectional view of a semiconductor device according to a first embodiment of the present invention, and a cross sectional view of a mounting structure using a Chip-on-Chip system, respectively;

FIGS. 2A to 2N are schematic cross sectional views, respectively, showing processes for manufacturing the semiconductor device according to the first embodiment of the present invention in order;

FIGS. 3A to 3I are schematic cross sectional views, respectively, showing processes for manufacturing a semiconductor device according to a second embodiment of the present invention in order;

FIGS. 4A to 4O are schematic cross sectional views, respectively, showing processes for manufacturing a semiconductor device according to the related art in order;

FIGS. 5A to 5D are schematic cross sectional views, respectively, showing processes for manufacturing a mounting structure using the Chip-on-Chip system according to the related art in order; and

FIGS. 6A and 6B are an enlarged schematic cross sectional view of a main portion of the semiconductor device shown in FIG. 4O, and a schematic sectional view of the mounting structure using the Chip-on-Chip system according to the related art, respectively.

### DETAILED DESCRIPTION OF THE PREFERRED EMBODIMENTS

In the present invention, for increasing a deposition strength of the solder bump electrode, preferably, the base metal layer functions as an under bump metal layer, and the under bump metal layer is formed from the pad electrode to an insulating film partially covering the pad electrode.

In this case, preferably, a nickel under bump metal layer is formed on an aluminum pad electrode, and a tin system solder bump electrode is formed on the nickel under bump metal layer.

Also, preferably, for increasing a strength of the solder bump electrode itself, a copper system metallic thin film is interposed in a joining region between the nickel under bump metal layer and the tin system solder bump electrode.

In addition, in a Chip-on-Chip mounting structure in which the plurality of semiconductor devices each described above are joined to one another through the solder bump electrodes, from the reason described above, preferably, the plurality of semiconductor devices are joined to one another in a fluxless fashion.

Preferably, the base metal layer is formed by electrolytic plating, and a material layer composing the solder bump electrode is formed by electrolytic plating.

Or, preferably, the base metal layer is formed by electrolytic plating, and a material layer composing the solder bump electrode is formed by physical evaporation (such as vacuum evaporation).

In addition, preferably, after the base metal layer is covered with a material composing the solder bump electrode, reflow is carried out under deposition of a solder flux, thereby forming the solder bump electrode.

The preferred embodiments of the present invention will be described concretely and in detail hereinafter with reference to the accompanying drawings.

### 1. First Embodiment

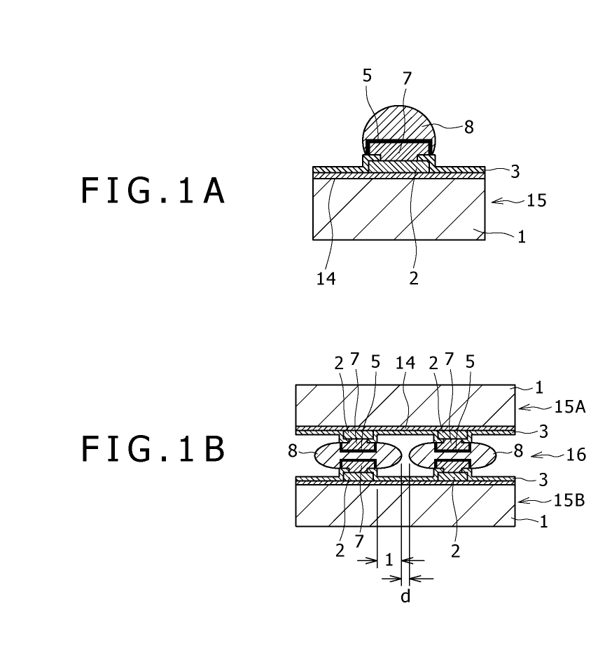

FIGS. 1A and 1B schematically show a structure of a semiconductor device (semiconductor chip) 15 according to a first embodiment of the present invention.

The semiconductor device 15 is composed of a semiconductor substrate 1 made of Si or the like, a pad electrode 2 made of aluminum, an insulating film 14 (corresponding to the insulating film 64 previously stated in the related art), a protective film 3 (corresponding to the protective film 64 previously stated in the related art), a copper (Cu) electrolytic plating layer 5, a Ni electrolytic plating layer 7, a Sn system solder bump electrode 8, and the like. Also, an Under Bump Metal (UBM) layer is composed of the Ni electrolytic plating layer 7 and also the Cu electrolytic plating layer 5. A size of the solder bump electrode 8, for example, may be equal to or smaller than 30 μm in diameter and equal to or smaller than 15 μm in height.

As shown in FIG. 1A, it is important for the semiconductor device 15 of the first embodiment that the solder bump electrode 8 covers the side surface as well of the UBM layer 7. That is to say, when as shown in FIG. 1B, a mounting structure 16 using the Chip-on-Chip system is formed under the condition of the application of the heat, and the application of the pressure in the fluxless fashion similarly to the case of the above description about the mounting using the Chip-on-Chip system, an amount 1 of solder transversely running over (amount of protrusion) in a joining portion between the solder bump electrodes 8 of an upper semiconductor device 15A and a lower semiconductor device 15B joined to each other decreases so as to correspond to adhesive amounts to the side surfaces of the UBM layers 7. As a result, the solder bump electrodes 8 which are disposed adjacent and close to each other in the transverse direction (in the planar direction) come not to contact each other mechanically as well as electrically even when the surface oxide film tears due to the pressure. Thus, it is possible to prevent the short-circuit from being generated between the solder bump electrodes 8.

In addition, when an underfill material (not shown) such as an epoxy resin is filled in a space defined between both the upper and lower semiconductor devices 15A and 15B, the solder bump electrodes 8 disposed adjacent to each other in each of the upper and lower semiconductor devices 15A and 15B are separated at a distance, d, from each other. However, the distance, d, becomes relatively larger than that in the related art because the amount of solder running over is reduced. As a result, the Sn elements as the material composing the solder bump electrode 8 is prevented from moving through the underfill material, and from generating the electromigration. For this reason, it is also possible to increase margins of the distance, d, and disposition of the solder bump electrodes which are designed so as to cope with the electromigration.

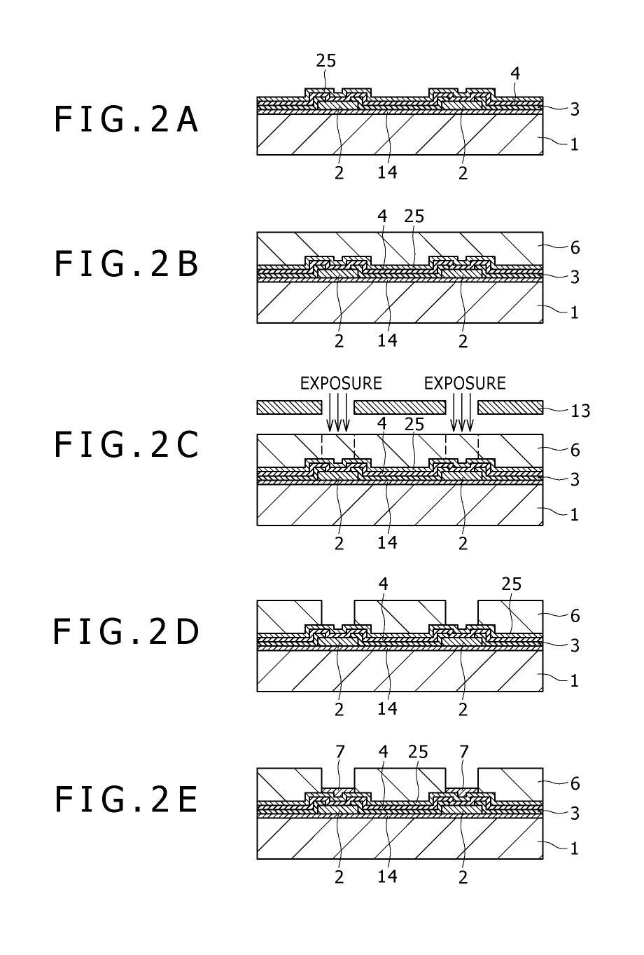

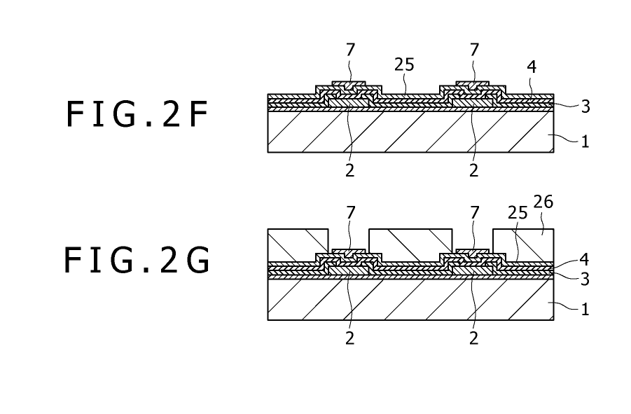

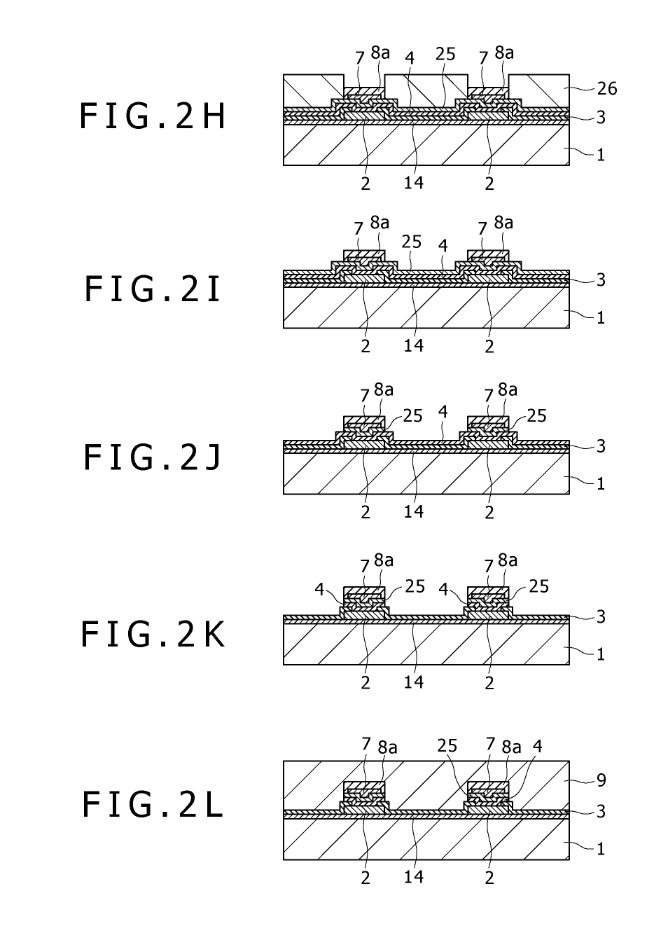

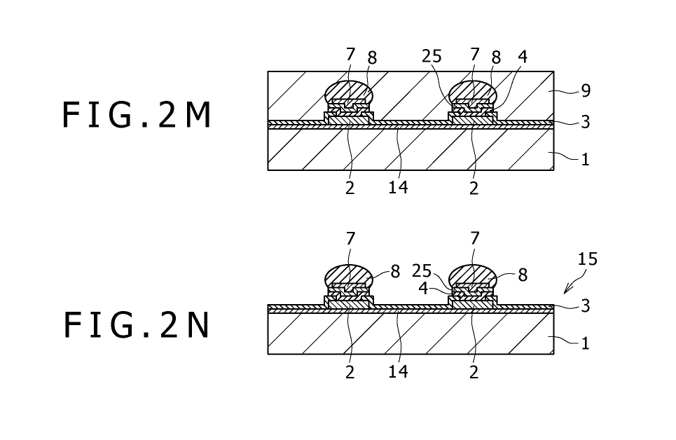

FIGS. 2A to 2N show the semiconductor device (semiconductor chip) according to the second embodiment of the present invention, and processes for manufacturing the semiconductor device, respectively.

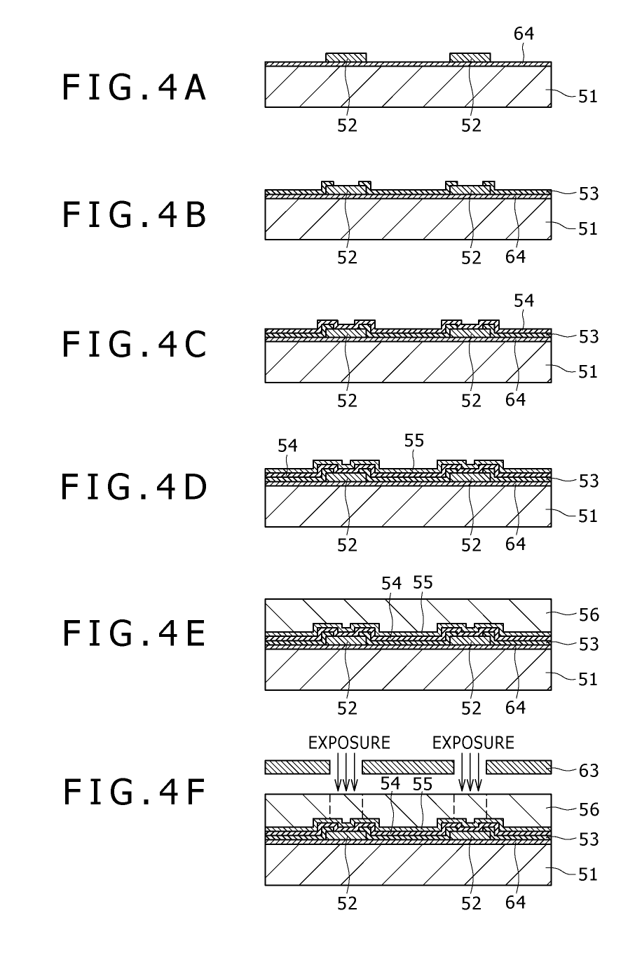

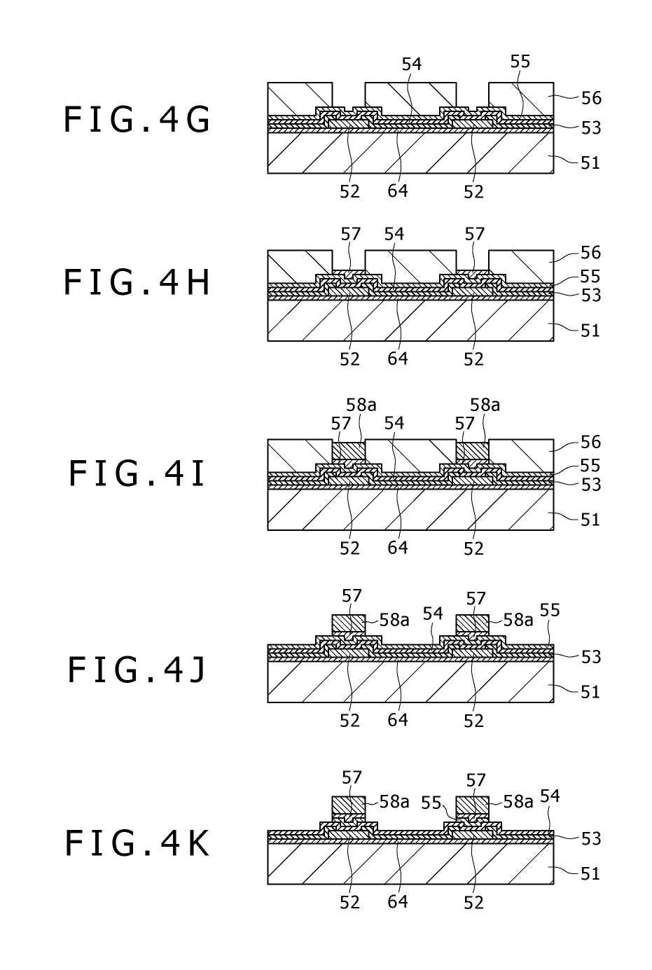

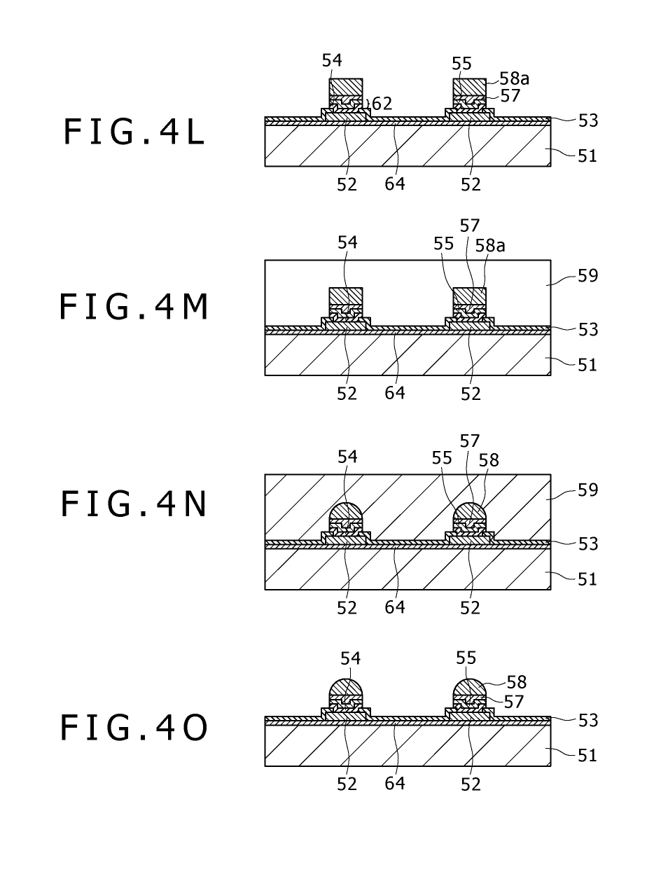

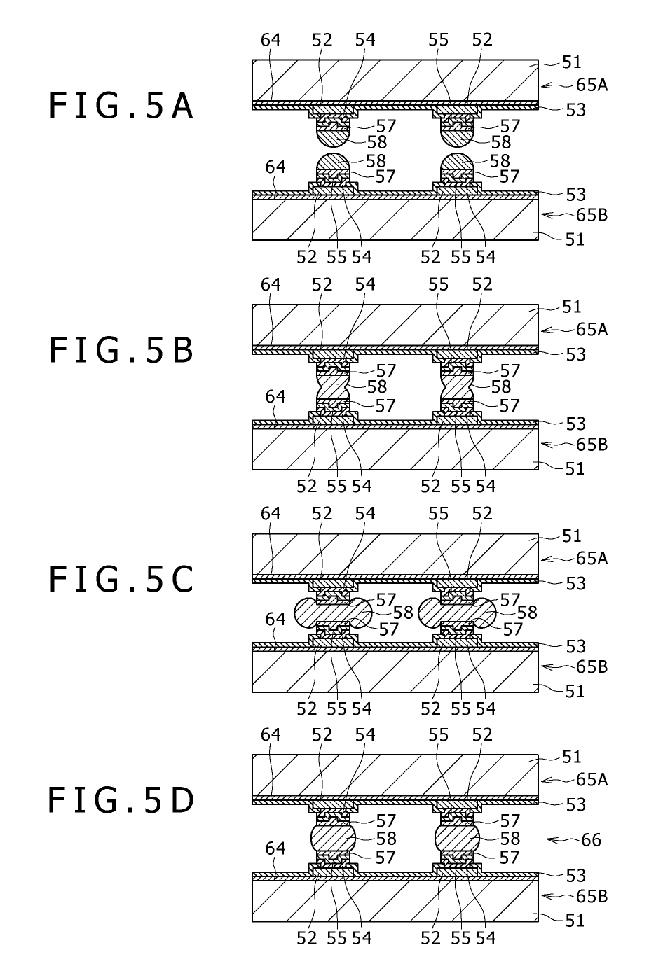

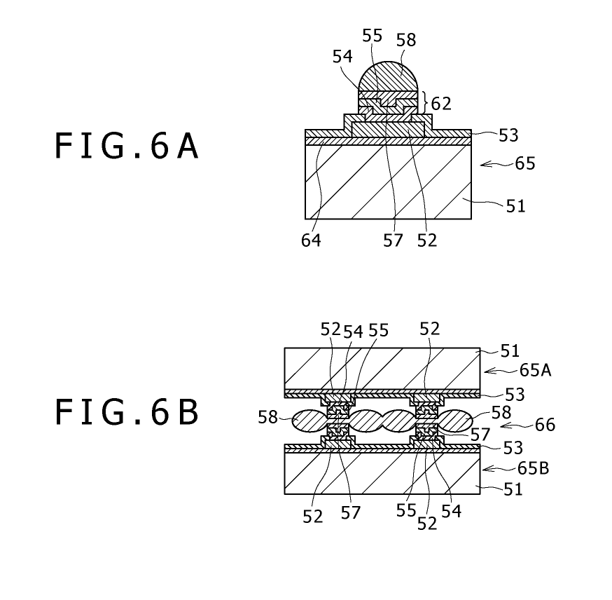

Firstly, as shown in FIG. 2A, similarly to the case of the description given with reference to FIGS. 4A to 4D, the insulating film 14, the pad electrode 2, the protective film 3, a Ti sputtering layer 4, and a Cu sputtering layer 25 are formed in this order on the semiconductor substrate 1.

Next, as shown in FIG. 2B, a positive photo resist 6 is applied onto the Cu layer 25.

Next, as shown in FIG. 2C, the positive photo resist 6 is selectively exposed by using a mask 13.

Next, as shown in FIG. 2D, an exposed portion of the positive photo resist 6 which is subjected to the exposure is dissolved and removed away by development.

Next, as shown in FIG. 2E, the Ni electrolytic plating layer 7 is formed on an exposed portion which is obtained by the selective removal of the positive photo resist 6 by the electrolytic plating.

Next, as shown in FIG. 2F, the positive photo resist 6 is entirely removed away.

Next, as shown in FIG. 2G, a photo resist 26 is formed in a predetermined pattern by the exposure and the development so as to expose the side surface of the Ni layer 7.

Next, as shown in FIG. 2H, the Sn electrolytic plating layer 8a is formed by the electrolytic plating.

Next, as shown in FIG. 2I, the photo resist 26 is removed away.

Next, as shown in FIG. 2J, the Cu layer 25 is selectively etched away except for a portion of the Cu layer 25 underlying the Sn electrolytic plating layer 8a with the Sn electrolytic plating layer 8a as an etching mask.

Next, as shown in FIG. 2K, a Ti layer 4 is selectively etched away except for a portion of the Ti layer 4 underlying the Sn electrolytic plating layer 8a with the Sn electrolytic plating layer 8a as an etching mask.

Next, as shown in FIG. 2L, the flux layer 9 is formed so as to cover the Sn electrolytic plating layer 8a.

Next, as shown in FIG. 2M, the solder bump electrode 8 is formed by carrying out the reflow treatment.

Next, as shown in FIG. 2N, the flux layer 9 is removed away and the cleaning is carried out, thereby manufacturing the semiconductor device (semiconductor chip) 15.

In this embodiment, since the solder bump electrode 8 is also formed by the electrolytic plating, all the processes can be readily carried out by using the Cu layer 25 as the electrode, and the solder bump electrode 8 can also be thickly formed.

### 2. Second Embodiment

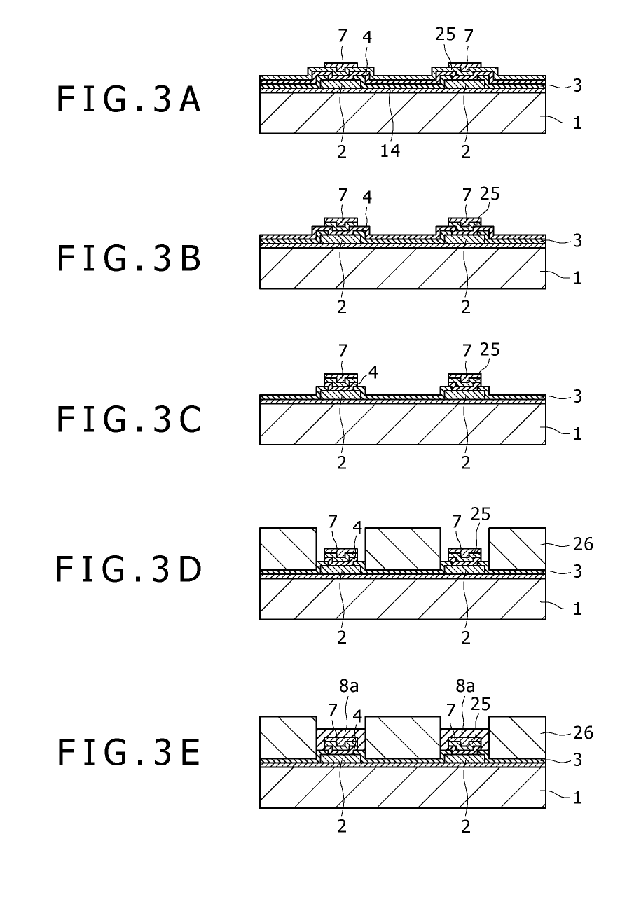

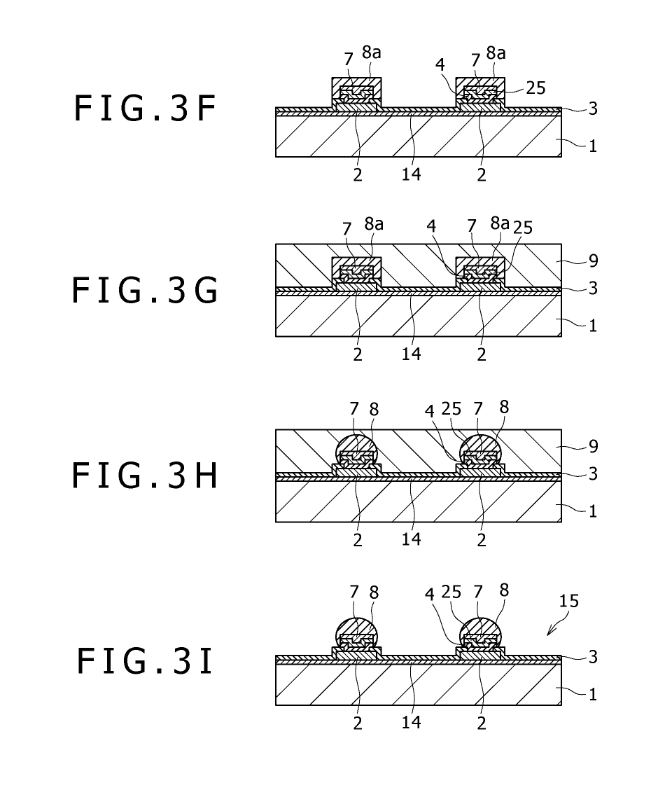

FIGS. 3A to 3I show a semiconductor device according to a second embodiment of the present invention, and processes for manufacturing the semiconductor device of the second embodiment, respectively.

Firstly, similarly to the case of the description given with reference to FIGS. 4A to 4H, the insulating film 14, the pad electrode 2, the protective film 3, the Ti sputtering layer 4, the Cu sputtering layer 25, and the Ni electrolytic plating layer 7 are formed in this order on the semiconductor substrate 1.

Next, as shown in FIG. 3B, the Cu sputtering layer 25 is selectively etched away with the Ni electrolytic plating layer 7 as an etching mask except for a portion of the Cu sputtering layer 25 underlying the Ni electrolytic plating layer 7.

Next, as shown in FIG. 3C, the Ti sputtering layer 4 is selectively etched away with the Ni electrolytic plating layer 7 as an etching mask except for a portion of the Ti sputtering layer 4 underlying the Ni electrolytic plating layer 7.

Next, as shown in FIG. 3D, the photo resist 26 is formed in a predetermined pattern by the exposure and the development on the protective film 3 so as to expose the side surfaces of the Ni electrolytic plating layer 7, the Cu sputtering layer 25 and the Ti sputtering layer 4.

Next, as shown in FIG. 3E, a Sn—Ag alloy evaporation layer 8a is formed by the vacuum evaporation (especially, oblique evaporation) so as to cover the side surfaces of the Ni electrolytic plating layer 7, the Cu sputtering layer 25 and the Ti sputtering layer 4. In this case, the Sn—Ag alloy evaporation layer 8a may also be formed by using the sputtering method.

Next, as shown in FIG. 3F, the photo resist layer 26 is removed away.

Next, as shown in FIG. 3G, the flux layer 9 is formed so as to cover the Sn—Ag alloy evaporation layer 8a.

Next, as shown in FIG. 3H, the solder bump electrode 8 is formed by carrying out the reflow treatment.

Next, as shown in FIG. 3I, the flux layer 9 is removed away and the cleaning is carried out, thereby manufacturing the semiconductor device (semiconductor chip) 15.

In the second embodiment of the present invention, since the Sn—Ag solder material layer 8a is formed by the vacuum evaporation, the solder material layer 8a can be reliably deposited so as to have a sufficient thickness. The remaining respects are the same as those in the first embodiment described above.

Although the present invention has been described so far based on the embodiments, it goes without saying that the present invention is by no means limited thereto, and changes can be suitably made without departing from the subject matter of the present invention.

For example, not only aluminum, but also copper having a lower electric resistance than that of aluminum can be adopted as the material for the pad electrode 2. In addition, the sputtering can be applied instead of applying the vacuum evaporation.

The semiconductor devices according to the embodiments of the present invention are suitable for the highly reliable mounting structure, using the Chip-on-Chip system, in which the short-circuit is hardly generated, and can be applied to the manufacture of various kinds of electronic apparatuses.

The present application contains subject matter related to that disclosed in Japanese Priority Patent Application JP 2010-026484 filed in the Japan Patent Office on Feb. 9, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device, comprising:
a semiconductor chip having a semiconductor substrate;
a pad electrode formed on said semiconductor substrate;
a base metal layer formed on said pad electrode; and
a solder bump electrode formed on said base metal layer,
wherein an exposed surface including a side surface of said base metal layer is covered with said solder bump electrode.

2. The semiconductor device according to claim 1, wherein said base metal layer functions as an under bump metal layer, and said under bump metal layer is formed from said pad electrode to an insulating film partially covering said pad electrode.

3. The semiconductor device according to claim 2, wherein a nickel under bump metal layer is formed on an aluminum pad electrode, and a tin system solder bump electrode is formed on the nickel under bump metal layer.

4. The semiconductor device according to claim 3, wherein a copper system metallic thin film is interposed in a joining region between said nickel under bump metal layer and said tin system solder bump electrode.

5. A Chip-on-Chip mounting structure, comprising
a plurality of semiconductor devices each including a semiconductor chip having a semiconductor substrate, a pad electrode formed on said semiconductor substrate, a base metal layer formed on said pad electrode, and a solder bump electrode formed on said base metal layer,
wherein an exposed surface including a side surface of said base metal layer is covered with said solder bump electrode, and
said plurality of semiconductor devices are joined to one another through the solder bump electrodes.

6. The Chip-on-Chip mounting structure according to claim 5, wherein said plurality of semiconductor devices are joined to one another in a fluxless fashion.

7. A method of manufacturing a semiconductor device, comprising the steps of:
forming a pad electrode on a semiconductor substrate;
forming a base metal layer on said pad electrode; and
forming a solder bump electrode on said base metal layer, an exposed surface including a side surface of said base metal layer being covered with a material composing said solder bump electrode.

8. The method of manufacturing a semiconductor device according to claim 7, wherein said base metal layer is formed by electrolytic plating, and a material layer composing said solder bump electrode is formed by physical evaporation.

9. The method of manufacturing a semiconductor device according to claim 7, wherein after said base metal layer is covered with a material composing said solder bump electrode, reflow is carried out under deposition of a solder flux, for forming said solder bump electrode.

10. A method of forming a Chip-on-Chip mounting structure, comprising the steps of:
causing a plurality of semiconductor devices each obtained by a manufacturing method to contact one another through the solder bump electrodes, said manufacturing method including the steps of forming a pad electrode on a semiconductor substrate, forming a base metal layer on said pad electrode, and forming a solder bump electrode on said base metal layer, an exposed surface including a side surface of said base metal layer being covered with a material composing said solder bump electrode;
melting said solder bump electrodes under a condition of application of heat, and application of pressure in this state; and
solidifying said solder bump electrodes, for joining said plurality of semiconductor devices to one another.
